(19) United States
(12) Patent Application Publication
(10) Pub. No.: US 2020/0073155 A1
(43) Pub. Date: Mar. 5, 2020

(54) ELECTRONIC COMPONENT BOARD, DISPLAY PANEL, AND METHOD OF PRODUCING THEM

(71) Applicant: Sharp Kabushiki Kaisha, Sakai City (JP)

(72) Inventors: Hideki KITAGAWA, Sakai City (JP); Yoshihito HARA, Sakai City (JP); Masaki MAEDA, Sakai City (JP); Tatsuya KAWASAKI, Sakai City (JP); Yoshiharu HIRATA, Sakai City (JP); Hajime IMAI, Sakai City (JP); Tohru DAITOH, Sakai City (JP)

(21) Appl. No.: 16/535,313

(22) Filed: Aug. 8, 2019

Related U.S. Application Data
(60) Provisional application No. 62/725,295, filed on Aug. 31, 2018.

(51) Int. Cl. G02F 1/03; G02F 1/1362; H01L 27/12

(52) U.S. Cl. CPC G02F 1/0311; H01L 27/1214; G02F 1/1362

(57) ABSTRACT

An electronic component board includes a conductive film, an insulating film, and a transparent electrode film. The insulating film is disposed in a layer upper than the conductive film to cover a side surface and an upper surface of the conductive film. The transparent electrode film is disposed in a layer upper than the insulating film. The transparent electrode film includes an electrode portion and a covering portion. The electrode portion includes an electrode. The electrode portion is electrically connected to the conductive film. The covering portion is separated from the electrode portion and electrically insulated from the conductive film and the electrode portion to overlap the conductive film and the insulating film that covers the conductive film.

### CROSS REFERENCE TO RELATED APPLICATION

This application claims priority from U.S. Provisional Patent Application No. 62/725,295 filed on Aug. 31, 2018. The entire contents of the priority application are incorporated herein by reference.

### TECHNICAL FIELD

The technology described herein relates to an electronic component board, a display panel, and a method of producing them.

### BACKGROUND ART

A display panel that has a configuration in which an electrooptic material such as a liquid crystal is sealed between two boards that are opposed to each other has been known. One of the boards is an electronic component board that includes at least thin film transistors (TFTs) and pixel electrodes. The TFTs function as switching components. The pixel electrodes are disposed in a layer upper than the TFTs via an insulating film. In a display area of the electronic component board, signal lines that include gate lines and source lines are disposed in a grid. Each TFT is disposed at an intersection of the signal lines. The pixel electrodes are disposed in cells of the grid defined by the lines. As a result, pixels, which are display units, are formed. Each TFT includes a gate electrode, a source electrode, a drain electrode, and a channel region. The gate electrode and the source electrode are prepared from a conductive film and connected to the signal lines, respectively. The drain electrode is prepared from a conductive film and connected to the pixel electrode. The channel region is prepared from a semiconductor film to connect the source electrode to the drain electrode. In such a display panel, when electrical signals that are supplied from an external device to the signal lines are transmitted to the pixel electrodes via the TFTs with predefined timing and electric fields are applied to the electrooptic material, optical characteristics of the electrooptic material vary and images are displayed in the display area.

In general, a light blocking layer is disposed in non-display areas such as areas in which the gate lines and source lines are disposed and areas that overlap areas in which the TFTs are disposed. To improve aperture ratios by reducing the areas of the light blocking layer for improving the definition and brightness of display images, it is preferable that widths of the lines and the areas of the TFTs are reduced. However, if the widths of the lines are simply reduced, electrical resistances increase. Japanese Unexamined Patent Application Publication No. 2005-317983 discloses a semiconductor device in which lines are prepared from a multilayer film that contains aluminum (Al) that has lower electrical resistance to reduce electrical resistances of the lines.

Another method of reducing the electrical resistances of the lines without reducing the aperture ration may include increasing the thickness. If the thickness of the gate metal film that forms the gate electrodes of the TFTs is increased, the gate resistance can be reduced. However, if the thickness of the gate metal film is increased, steps formed due to the gate metal film increase and the gate insulating film that covers the side surfaces and the top surface of the gate metal film may not be tolerate the steps. As a result, cracks may occur in the gate insulating film. Because the side surfaces and the top surface of the conductive film on the substrate are covered with the insulating film, water from above the electronic component board is blocked by the insulating film and less likely to reach the conductive film. However, if the crack is present in the insulating film, the water may reach the conductive film through the crack and affect conductive performance. For example, if the crack is present in the gate insulating film, the gate resistance may vary and the TFT may malfunction. The thickness of the insulating film may be increased so that the crack is less likely to present in the insulating film. However, if the thickness of the insulating film that is formed substantially in solid on the substrate is increased, a stress caused by the insulating film may increase and problems including a warp of the substrate may occur.

### SUMMARY

The technology described herein was made in view of the above circumstances. An object is to restrict moisture from reaching a conductive film and to provide an electronic component board with higher reliability.

### Means for Solving the Problem

An embodiment of the technology described herein is an electronic component board that includes a conductive film, an insulating film, and a transparent electrode film. The insulating film is disposed in a layer upper than the conductive film to cover a side surface and an upper surface of the conductive film. The transparent electrode film is disposed in a layer upper than the insulating film. The transparent electrode film includes an electrode portion and a covering portion. The electrode portion includes an electrode. The electrode portion is electrically connected to the conductive film. The covering portion is separated from the electrode portion and electrically insulated from the conductive film and the electrode portion to overlap the conductive film and the insulating film that covers the conductive film.

### BRIEF DESCRIPTION OF THE DRAWINGS

FIG. 1 is a schematic view illustrating a brief cross-sectional configuration of a portion in a display area of a liquid crystal panel according to an embodiment.

FIG. 2 is a schematic view illustrating a brief two-dimensional configuration of pixels in a display area of an electronic component board.

FIG. 3 is a schematic view illustrating a brief cross-sectional configuration of a portion in which a TFT is disposed.

FIG. 4 is a schematic view illustrating a brief cross-sectional configuration of a portion of an electronic component board in which a TFT is disposed without a covering portion in a comparative example.

### DETAILED DESCRIPTION

### Embodiment

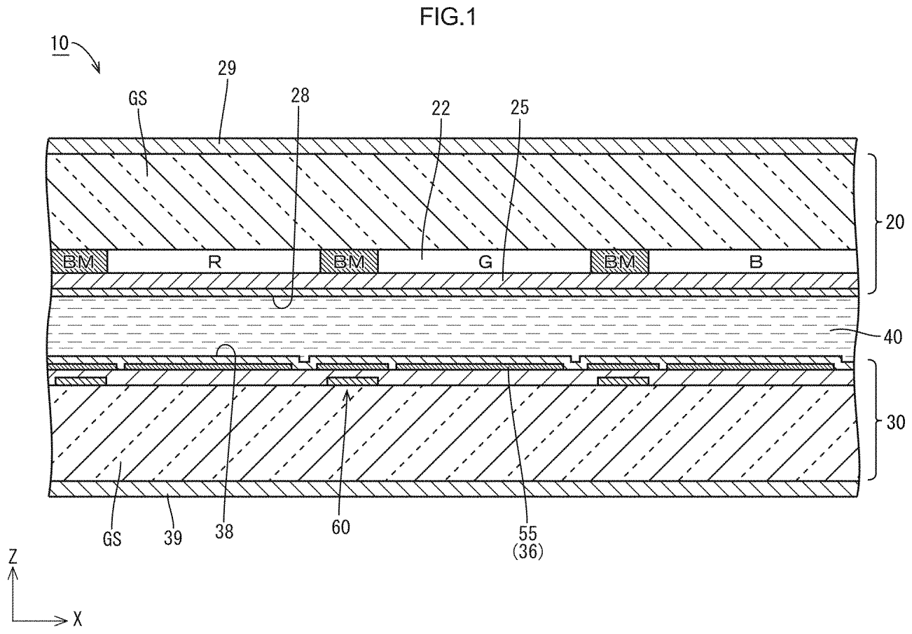

An embodiment will be described with reference to FIGS. 1 to 4. In this embodiment section, a liquid crystal panel 10 (an example of a display panel) will be described. X-axes, Y-axes, and Z-axes may be present in the drawings. The axes in each drawing correspond to the respective axes in other drawings. Dimensions of the structures and areas in the X-axis direction may be referred to as X dimensions. Dimensions of the structures and areas in the Y-axis direction may be referred to as Y dimensions. An upper side in FIG. 1 corresponds to a front side (and a lower side in FIG. 1 corresponds to a rear side or a back side) of the liquid crystal panel 10. For multiple components having the same configuration, only one of those components may be indicated by a reference number and others may not be indicated by the reference number. In each drawing, the structures may be schematically illustrated and some of dimensions may be in scales that are different from others.

The liquid crystal panel 10 may be used for a display panel in a display device includes in a smartphone or a tablet-type portable terminal. The technology described herein is especially preferable for a display panel that is required to have higher definition and brightness. The liquid crystal panel 10 has a screen size in a range from some inches to a dozen inches, which is generally classified into a small size or a small-to-middle size panel. The screen size is not limited to the above range. The technology described herein may be applied to display panels having screen sizes in several inches, which are generally classified into a middle size or a large size (or an extra-large size) panels.

The liquid crystal panel 10 in this embodiment is a transmissive liquid crystal panel. The liquid crystal panel 10 includes a front plate surface that is configured as a display surface on which images are displayed. The liquid crystal panel 10 is configured to display images that are viewed from the front side. A backlight unit, which is not illustrated, is disposed behind the liquid crystal panel. The liquid crystal panel 10 is illuminated with light from the backlight unit from the back side. The liquid crystal panel 10 may have a known configuration. As illustrated in FIG. 1, the liquid crystal panel 10 includes boards 20 and 30 including plate surfaces that are opposed to each other and bonded together. The boards 20 and 30 are bonded together by a sealant, which is not illustrated, with a predefined gap therebetween. The sealant may be made of epoxy resin. A space between the boards 20 and 30 is filled with a liquid crystal material to form a liquid crystal layer 40. Orientation of the molecules in the liquid crystal material varies when electrical signals are supplied. A known material may be used for the liquid crystal material. In this embodiment, a negative-type nematic liquid crystal material is used. In an initial state in which no voltage is applied between the boards 20 and 30 (a non-energized state), the molecules are orientated substantially perpendicular to the plate surfaces of the boards 20 and 30. Namely, the liquid crystal panel 10 operates in vertical alignment (VA) mode. A vacuum filling method or a one drop filling method may be used for filling a space between the boards 20 and 30 with the liquid crystal material. With the vacuum filling method, the boards 20 and 30 are bonded together and the liquid crystal material is drawn into the space between the boards 20 and 30 with a reduce pressure. With the one drop filling method, the liquid crystal material is dropped onto one of the boards during the bonding of the boards 20 and 30.

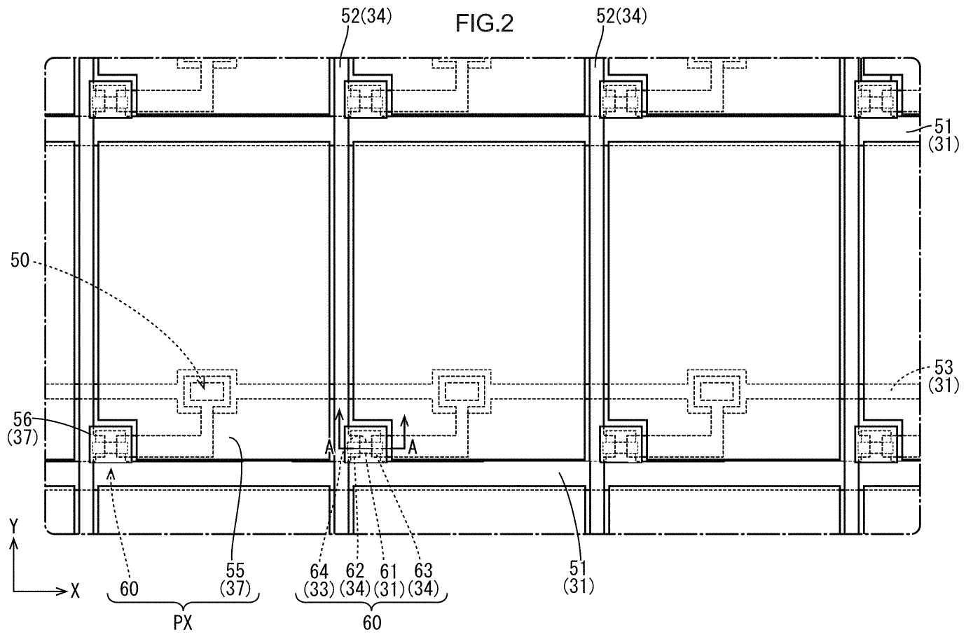

One of the boards 20 and 30 illustrated in FIG. 1 on the front is defined as a color filter (CF) board 20 (may be referred to as a common board). The other one on the back is defined as an electronic component board 30 (may be referred to as a device board, an array board, a matrix board, or a thin film transistor board (a TFT board)). A display area (an active area) in which images can be displayed is defined in the middle of the plate surface of the liquid crystal panel 10. In this area, pixels PX are provided (see FIG. 2), which will be described later. Although details are not illustrated or described, terminals are provided in a frame area that is a non-display area. Signal transmission components for transmitting electrical signals and driving components for displaying images in the display area are connected or mounted to the terminals.

As illustrated in FIG. 1, the boards 20 and 30 include glass substrates GS, respectively. The glass substrates GS are substantially transparent to pass visible light. The glass substrates GS have insulating properties. In this embodiment, the glass substrates GS are used. However, silicon substrates or heat-resistant plastic substrates may be used instead of the glass substrates GS. The CF board 20 and the electronic component board 30 may include light transmissive substrates mate of different materials. Polarizing plates 29 and 39 are bonded to outer surfaces (on opposite sides from the liquid crystal layer) of the boards 20 and 30. The polarizing plates 29 and 39 are prepared by stretching transparent films that are impregnated with iodine or dye. Different kinds of films are stacked on inner surfaces (closer to the liquid crystal layer 40, surfaces opposed to each other) of the glass substrates GS. The films are formed in predefined patterns by a known film forming method, for example, a photolithography method. Alignment films 28 and 38 are form on innermost surfaces of the boards 20 and 30, that is, the surfaces that contact the liquid crystal layer 40. Polyimide films are used for the alignment films 28 and 38. The alignment films 28 and 38 are bonded to the boards 20 and 30 such that alignment surfaces of the alignment films 28 and 38 are opposed to each other after required alignment processing that includes rubbing and photo-alignment.

In this embodiment section, the liquid crystal panel 10 that includes a common electrode 25 on the CF board 20 and operates in vertical alignment (VA) mode will be described. As illustrated in FIG. 1, a color filter 22 that include color portions R, G, and B is disposed on the inner surface (closer to the liquid crystal layer 40) of the CF board 20 in the display area. The color filter 22 is configured to selectively pass light rays in red (R), green (G), and blue (B) colors. The common electrode 25 is disposed in a layer upper than the color filter 22 (closer to the inner surface or the liquid crystal layer). The color filter 22 includes a black matrix BM that is disposed at boards among the color portions R, G, and B. The black matrix BM is disposed to cover non-pixel portions of the electronic component board 30 (areas in which lines, the TFTs 60, and contact holes 50, which will be described later, in the display area), which will be described later. The common electrode 25 is prepared from a transparent electrode film that contains transparent metal oxide such as indium tin oxide (ITO) and indium zinc oxide (IZO). The transparent electrode film used for the common electrode 25 is formed in a solid pattern in a layer upper than the color filter 22 on the CF board 20 to cover a whole area.

As illustrated in FIG. 1, different kinds of structural objects that include the TFTs 60 and pixel electrodes 55 (electrode portions) are disposed on the inner surface closer to the liquid crystal layer 40) of the electronic component board 30. In FIG. 1, the structural objects are simplified and the stacked films are not illustrated in detail. In this embodiment section, the electronic component board 30 that includes the TFTs 60 that are inversely staggered TFTs will be described. On the inner surface of the electronic component board 30, a first metal film 31 (a gate metal film, an example of a conductive film), a gate insulating film 32 (an example of an insulating film), a semiconductor film 33, a second metal film 34 (a source metal film, an example of another conductive film), a protective insulating film 35 (a passivation film, a PAS film, an example of another insulating film), an organic insulating film 36 (a JAS film, a planarization film, an example of another insulating film), a transparent electrode film 37, and the alignment film 38 are disposed in this sequence from a lower layer side and formed in predefined patterns.

Among the films, each of the first metal film 31 and the second metal film 34 is prepared from a single-layer film made of one kind of metal selected from copper (Cu), titanium (Ti), aluminum (Al), molybdenum (Mo), and tungsten (W). Each of the gate insulating film 32 and the protective insulating film 35 is made of silicon nitride (SiNx) or silicon oxide (SiO₂). The semiconductor film 33 may be a silicon thin film or an oxide thin film. The silicon thin film may be made of amorphous silicon or low temperature polycrystalline silicon. The oxide thin film is prepared from one kind of an oxide semiconductor that contains indium (In), gallium (Ga), and zinc (Zn). The organic insulating film 36 may be prepared from an acrylic-based resin film (e.g., polymethylmethacrylate resin (PMMA)). The transparent electrode film 37 may be made of a transparent electrode material that contains a transparent metal oxide such as ITO and ZnO.

With the films, the TFTs 60 and the pixel electrodes 55 are arranged in a matrix along a row direction (the X-axis direction) and a column direction (the Y-axis direction) on the inner surface of the electronic component board 30 in the display area as illustrated in FIG. 2. The TFTs 60 are switching components (display components). Gate lines 51 (gate bus lines, row lines, row control lines, scanning lines) and source lines 52 (source bus lines, column lines, column control lines, data lines) are routed in a grid to surround the TFTs 60 and the pixel electrodes 55. The gate lines 51 and the source lines 52 are prepared from the first metal film 31 and the second metal film 34, respectively. The gate insulating film 32 is disposed between intersections of the gate lines 51 and the source lines 52. Furthermore, capacitive lines 53 are prepared from the first metal film 31 and disposed parallel to the gate lines 51 and crossing the pixel electrodes 55.

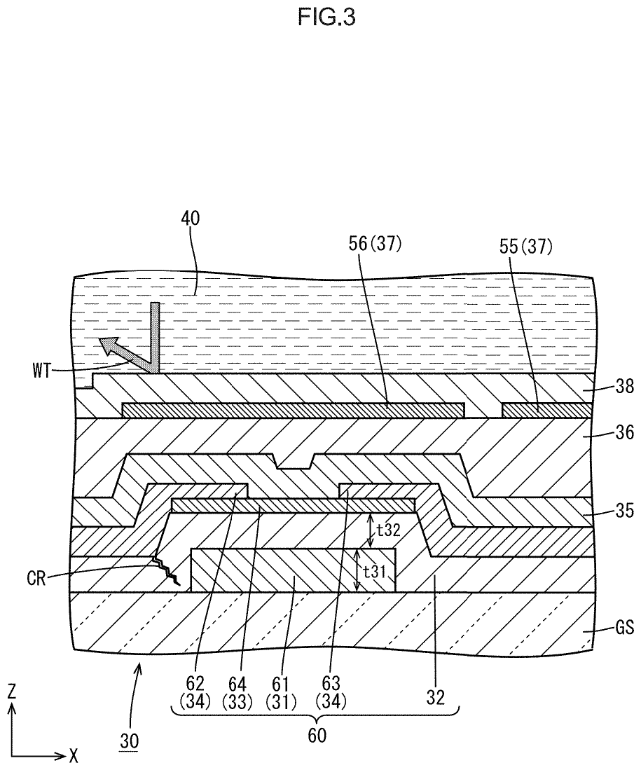

FIG. 3 schematically illustrates a cross-sectional configuration of the electronic component board 30 including the TFTs 60. In this embodiment section, the TFTs 60 that are inversely staggered TFTs will be described. As illustrated in FIG. 3, the TFTs 60 includes gate electrodes 61, source electrodes 62, drain electrodes 63, and channel regions 64. The gate electrodes 61 are prepared from the first metal film 31. The source electrodes 62 and the drain electrodes 63 are prepared from the second metal film 34. The channel regions 64 are prepared from the semiconductor film 33. The channel regions prepared from the semiconductor film 33 are stacked in a layer upper than the gate electrodes 61 prepare from the first metal film 31 via the gate insulating film 32. The source electrodes 62 and the drain electrodes 63 prepared from the second metal film 34 are disposed in a layer upper than the semiconductor film 33. As illustrated in FIG. 2, the gate electrodes 61 of the TFTs 60 prepared from the first metal film 31 are connected to the gate lines 51 prepared from the first metal film 31. The source electrodes 62 prepared from the second metal film 34 are connected to the source lines 52 prepared from the second metal film 34. The TFTs 60 are connected to the pixel electrodes 55 via the contact holes 50 that are through holes formed in the protective insulating film 35 and the organic insulating film 36 at positions that overlap the capacitive lines 53. According to the arrangement of the contact holes 50, the area of the black matrix BM is maintained as small as possible to maintain the aperture ratio high.

As illustrated in FIG. 2, each of the pixel electrodes 55 has a rectangular shape in a plan view. The pixel electrodes 55 are prepared from the transparent electrode film 37 that is disposed in a layer upper than the second metal film 34 with the protective insulating film 35 and the organic insulating film 36 therebetween.

As illustrated in FIG. 2, each pixel electrode 55 and the TFT 60 connected to the pixel electrode 55 in the electronic component board 30 form the pixel PX. The pixel PX exhibits the color corresponding the color portions R, G, or B of the color filter 22 opposed to the pixel electrode 55 in that pixel PX. As described earlier, with the external signal source connected to the frame region, the common electrode 25 is maintained at a reference potential. When a voltage is applied to each pixel electrode 55 based on an electronic signal supplied from the driving circuit in the frame region through the gate lines 51 and the source lines 52, a potential difference is created between the pixel electrode 55 and the common electrode 25. The orientation of the molecules in the liquid crystal layer 40 varies based on the potential difference. The polarization of transmitting light varies as the orientation of the molecules varies. An amount of the light transmitting through the liquid crystal panel 10 is controlled by each pixel PX. Through the control, an image in specified color is displayed in the display area.

The electronic component board 30 in this embodiment includes covering portions 56 that are prepared from the transparent electrode film 37 and disposed to cover the tops of the TFTs 60. In the electronic component board 30 in this embodiment, to reduce the gate resistance of each TRT 60, a thickness of the first metal film 31 that forms the gate electrodes 61 is relatively large. A thickness t31 of each gate electrode 61 is set larger than a thickness t32 of the gate insulating film 32 (t31>t32). The gate insulating film 32 cannot tolerate steps formed by the gate electrodes 61 on the glass substrate GS and thus cracks CR may occur in the gate insulating film 32.

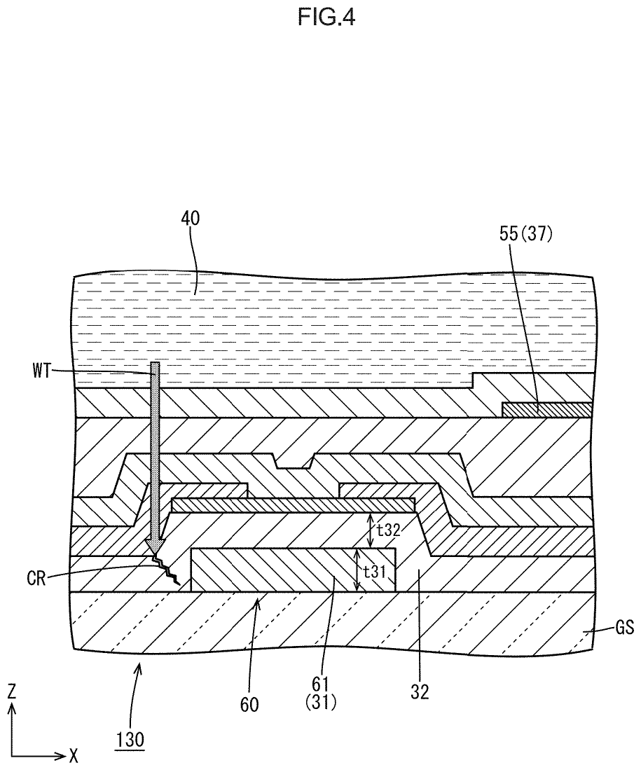

FIG. 4 is a schematic view that illustrates a brief cross-sectional configuration of a portion of a comparative example that includes an electronic component board 130 without the covering portions 56. The portion includes the TFT 60 and therearound. The configuration of the electronic component board 130 is similar to that of the electronic component board 30 except for the covering portions. The thickness t31 of each gate electrode is larger than the thickness t32 of the gate insulating film 32. In FIG. 4, a crack CR is present in the gate insulating film 32. In a liquid crystal panel, water WT may enter a liquid crystal layer through a sealing portion at a periphery of the panel in a certain environment. As illustrated in FIG. 4, the water WT from the liquid crystal layer 40 side may pass through the crack CR and reach the gate electrode 61 depending on a position of the crack CR in the gate insulating film 32. This may affect the gate resistance.

In the electronic component board 30 in this embodiment, as illustrated in FIG. 3, the covering portions 56 are disposed in the layer upper than the TFTs 60 to overlap the TFTs 60 from above. Therefore, the water WT from the liquid crystal layer 40 is blocked by the covering portions 56 that are prepared from the transparent electrode film 37. Even if the gate insulating film 32 has the crack CR, the water WT is less likely to reach the gate electrode 61. In comparison to the electronic component board 130 without the covering portions 56, the TFTs 60 can be stably driven.

Next, a method of producing the electronic component board 30 that has the above configuration will be described. The films in the electronic component board 30 can be formed by a known method without any limitations. The following processes (a) to (h) are examples but the technology described herein is not limited to the processes.

(a) The first metal film 31 is formed on the upper surface of the glass substrate GS (on the front side, the surface on the liquid crystal layer 40 side) by spattering. A photoresist film that includes portions to form the gate electrodes 61, the gate lines 51, and the capacitive lines 53 is formed on the first metal film 31. The portions are prepared by patterning. Portions of the first metal film 31 not covered with the photoresist film are removed by etching to form the gate electrodes 61, the gate lines 51, and the capacitive lines 53 ((A) a conductive film forming process). The photoresist film is removed by plasma asking using oxygen. In this embodiment, the first metal film 31 is formed with the thickness t31, which is relatively large.

(b) The gate insulating film 32 is formed on an upper surface of the first metal film 31 by a plasma CVD method. The gate insulating film 32 is formed in solid to cover side surfaces and upper surfaces of the gate electrodes 61, the gate lines 51, and the capacitive lines 53 ((B) an insulating film forming process). The thickness t32 of the gate insulating film 32 in this embodiment is set smaller than the thickness t31 of the first metal film 31 (t32<t31).

(c) The semiconductor film 33 is formed on an upper surface of the gate insulating film 32 by a plasma CVD method. Unnecessary portions of the semiconductor film 33 re removed by the photolithography method used in the process (a). Through this process, the channel regions 64 are prepared from the semiconductor film 33.

(d) The second metal film 34 is formed on an upper surface of the semiconductor film 33 by a plasma CVD method. Unnecessary portions are removed by the photolithography method used in the process (a). Through this process, the source electrodes 62, the drain electrodes 63, and the source lines 52 are prepared.

(e) The protective insulating film 35 and the organic insulating film 36 are formed on an upper surface of the second metal film 34 in sequence. The insulating films 35 and 36 may be formed in solid by a plasma CVD method.

(f) The contact holes 50 that are through holes are formed in the protective insulating film 35 and the organic insulating film 36.

(g) The transparent electrode film 37 is formed on an upper surface of the organic insulating film 36 that includes the contact holes 50 by spattering. A photoresist film that includes portions to form the pixel electrode 55 and the covering portions 56 using a photomask (a pattern) is formed on the transparent electrode film 37. Portions of the transparent electrode film 37 not covered with the photoresist film are removed by etching. Through the process, the pixel electrodes 55 and the covering portions 56 are prepared at the same time ((C) a transparent electrode forming process). The pixel electrodes 55 are connected to the conductive lines 53 that are exposed to bottoms of openings in the contact holes 50. The covering portions 56 are separated and insulated from the pixel electrodes 55 and other conductive films.

(h) The alignment film 38 is formed on an upper surface of the transparent electrode film 37. Alignment processing may be performed as necessary. Through the processes, the electronic component board 30 is produced.

The liquid crystal panel 10 is provided with the electronic component board 30 that is produced as described above. The electronic component board 30 is bonded to the CF board 20, which is produced by a known method, with a known sealant. The space between the boards 20 and 30 is filled with the liquid crystal material using the one-drop filling method or the vacuum filling method.

As described earlier, the electronic component board 30 in this embodiment includes the first metal film 31 (the conductive film), the gate insulating film 32 (the insulating film), and the transparent electrode film 37. The gate insulating film 32 is disposed in the layer upper than the first metal film 31 to cover the side surfaces and the top surfaces of the first metal film 31. The transparent electrode film 37 is disposed in the layer upper than the gate insulating film 32. The transparent electrode film 37 includes portions configured as the pixel electrodes 55 (the electrode portions) and portions configured as the covering portions 56. The pixel electrodes 55 are electrodes electrically connected to the first metal film 31. The covering portions are separated from the pixel electrodes 55 and electrically insulated from the first metal film 31 and the pixel electrodes 55. The covering portions overlap the first metal film and the gate insulating film 32 that covers the first metal film 31.

According to the configuration of this embodiment, even if a crack is present in the gate insulating film 32 that covers the first metal film 31, the corresponding covering portion 56 blocks water from entering from above. Therefore, the water is less likely to reach the first metal film 31. As a result, failures due to the water that reaches the first metal film 31 are less likely to occur and thus the electronic component board 30 is provided with higher reliability. Because the covering portions 56 that block the water are prepared from the transparent electrode film 37 that forms the pixel electrodes 55, the pixel electrodes 55 and the covering portions 56 can be patterned with the photoresist film using the photomask and the material at the same time. This method has advantages in material procurement management, production process, and cost. The covering portion 56 are separated and electrically insulated from the first metal film 31 and the pixel electrodes 55. Therefore, the covering portions 56 do not affect the electrical performance of components prepared from the first metal film 31.

In the electronic component board 30 in this embodiment, the thickness t31 of the first metal film 31 is larger than the thickness t32 of the gate insulating film 32 (t31>t32).

According to the configuration of this embodiment, in the electronic component board 30 having the configuration in which the crack CR is more likely to be present in the gate insulating film 32 due to the increased thickness of the first metal film 31, the water is less likely to reach the first metal film 31. Therefore, the electronic component board 30 having less electrical resistances and higher reliability can be achieved.

The electronic component board 30 in this embodiment further includes the semiconductor film 33, the second metal film 34 (the other conductive film), the protective insulating film 35 (an example of the other insulating film) or the organic insulating film 36 (an example of the other insulating film). The semiconductor film 33 is disposed in the layer upper than the gate insulating film 32. The second metal film 34 is disposed on the semiconductor film 33. The protective insulating film 35 or the organic insulating film 36 is disposed in the layer upper than the second metal film 34. The transparent electrode film 37 is disposed in the layer upper than the protective insulating film 35 and the organic insulating film 36. The electronic component board 30 includes the TFTs 60 (an example of the transistors) that include the gate electrodes 61, the source electrodes, the drain electrodes 63, and the channel regions 64. The gate electrodes 61 are prepared from the first metal film 31. The source electrodes 62 and the drain electrodes 63 are prepared from the second metal film 34 and disposed above the semiconductor film 33 with the gap. Each channel region 64 is prepared from the semiconductor film 33 and disposed between a connecting portion with the source electrode 62 and a connecting portion with the drain electrode 63.

According to the configuration of this embodiment, in the electronic component board 30 that includes the inversely staggered-type TFTs 60 that include the gate electrodes 61 with the increased thickness and the reduced gate resistance, the water is less likely to enter the gate electrodes 61 and thus reliability improves.

The liquid crystal panel 10 in this embodiment is the display panel that includes the electronic component board 30.

According to the configuration of this embodiment, the liquid crystal panel 10 can be provided with lower driving power and higher reliability without a reduction in the aperture ratio.

The method of producing the electronic component board in this embodiment includes: (A) the conductive film forming process of forming the first metal film 31 on the glass substrate GS (the substrate); (B) the insulating film forming process of forming the gate insulating film 32 in the layer upper than the first metal film 31 to cover side surfaces and the top surfaces off the first metal film 31; and (C) the transparent electrode film forming process of forming the transparent electrode film 37 in the layer upper than the gate insulating film 32. The transparent electrode film 37 includes the covering portions 56 and the pixel electrodes 55. The covering portions 56 overlap the first metal film and the gate insulating film 32 that covers the first metal film 31. The pixel electrodes 55 are separated from the covering portions 56.

According to the configuration of this embodiment, the covering portion 56 restrict the water from reaching the first metal film 31. Therefore, the electronic component board 30 can be provided with higher reliability. The covering portions 56 that restrict the water are prepared from the transparent electrode film 37 that forms the pixel electrodes 55 in the transparent electrode film forming process in which the pixel electrodes 55 are prepared. This configuration has advantages in material procurement management and production process.

In the method of producing the electronic component board 30 in this embodiment, the covering portions 56 and the pixel electrodes 55 are formed at the same time through patterning using the pattern (e.g., the photoresist film using the photomask).

According to the configuration of this embodiment, the pixel electrodes and the covering portions 56 are formed through patterning using the pattern. Therefore, the covering portions 56 can be formed without an increase in complexity of the production process or in the number of components required for the production. Especially, the form the covering portions 56 and the pixel electrodes 55 are formed through patterning by etching without an increase in the number of expensive photomasks. This method has an advantage in reduction of the production cost.

The method of producing the liquid crystal panel 10 in this embodiment includes the production process of the electronic component board 30.

According to the configuration of this embodiment, the liquid crystal panel 10 can be provided with lower driving power and higher reliability without an increase in complexity of the production process or the production cost.

### OTHER EMBODIMENTS

The technology described herein is not limited to the embodiments described in the above descriptions and drawings. The following embodiments may be included in the technical scope of the technology described herein.

(1) Known materials may be used for the transparent electrode film, the insulating film, and the conductive film, that is, the materials are not limited to those described earlier. However, it is preferable that the transparent electrode film is provided with lower permeability. The transparent electrode film may be formed by a known method. The method of forming the transparent electrode film is not limited to a specific method. The transparent electrode film may be patterned to include the electrode portions and the covering portions by screen printing or by transferring instead of by etching.

(2) In the above embodiment, the liquid crystal panel 10 that is configured to operate in the VA mode. However, the image display mechanism and the operation mode of the liquid crystal panel are not limited to specific mechanism and mode. The technology described herein may be applied to liquid crystal panels each operate in in-plane switching (IPS) mode, fringe field switching (FFS) mode, twisted nematic (TN) mode, and other operation mode. Furthermore, application of the technology described herein is not limited to an electronic component board in a liquid crystal panel. The technology described herein may be applied to electronic component boards in other types of display panels (organic EL panels, plasma display panels (PDPs), electrophoretic display (EPD) panels, micro electro mechanical systems (MEMS)).

(3) The technology described herein may be applied to electronic component boards used for different uses other than the electronic component board used for the display panel.

1. An electronic component board comprising:
a conductive film;
an insulating film disposed in a layer upper than the conductive film to cover a side surface and an upper surface of the conductive film; and
a transparent electrode film disposed in a layer upper than the insulating film, wherein
the transparent electrode film includes:
an electrode portion including an electrode and being electrically connected to the conductive film; and
a covering portion separated from the electrode portion and electrically insulated from the conductive film and the electrode portion to overlap the conductive film and the insulating film covering the conductive film.

2. The electronic component board according to claim 1, wherein the conductive film has a thickness larger than a thickness of the insulating film.

3. The electronic component board according to claim 1, further comprising:
a semiconductor film disposed in a layer upper than the insulating film;
another conductive film disposed on the semiconductor film; and
another insulting film disposed in a layer upper than the other conductive film, wherein
the transparent electrode film is disposed in a layer upper then the other insulating film, and
the electronic component board further comprises a transistor including:
a gate electrode that is a portion of the conductive film;
a source electrode and a drain electrode that are portions of the other conductive film disposed above the semiconductor film with a gap; and
a channel region that is a portion of the semiconductor film and disposed between a connecting portion with the source electrode and a connecting portion with the drain electrode.

4. A display panel comprising the electronic component board according to claim 1.

5. A method of producing an electronic component board, the method comprising:
(A) a conductive film forming process of forming a conductive film on a substrate;
(B) an insulating film forming process of forming an insulating film in a layer upper than the conductive film to cover a side surface and a top surface of the conductive film; and
(C) a transparent electrode forming process of forming a transparent electrode film in a layer upper than the insulting film to include a covering portion to overlap the conductive film and the insulating film that covers the conductive film and an electrode portion separated from the covering portion.

6. The method according to claim 5, wherein the covering portion and the electrode portion are formed at a same time through patterning of the transparent electrode film using a pattern.

7. A method of producing a display panel, the method comprising the processes of the method of producing the electronic component board according to claim 5.
